(19) United States
(12) Patent Application Publication
(10) Pub. No.: US 2004/0018720 A1
(43) Pub. Date: Jan. 29, 2004

(54) Fabrication method for microstructures with high aspect ratios

(76) Inventors: Nai-Hao Kuo, Hsinchu (TW); Kai-Hsiang Yen, Hsinchu (TW); Jing-Hung Chiou, Hsinchu (TW); Po-Hao Tsai, Hsinchu (TW); Yuh-Wen Lee, Hsinchu (JP)

Correspondence Address: BIRCH STEWART KOLASCH & BIRCH, PO BOX 747, FALLS CHURCH, VA, 22040-0747, US

(21) Appl. No.: 10/424,789

(22) Filed: Apr. 29, 2003

(30) Foreign Application Priority Data
Jul. 23, 2002 (TW) 91116374

(51) Int. Cl. H01L 21/4763

(52) U.S. Cl. 438/637

(57) ABSTRACT

A fabrication method for microstructures with high aspect ratios is defined using via plugs and contact plugs. An etching channel is shaped as the microstructure is formed. Finally, an isotropic etching process is employed to remove the silicon substrate under the microstructure, thereby making a suspending microstructure with a high aspect ratio. In comparison with the prior art, the invention can save many photolithography steps and can be readily integrated into existing processes. Therefore, one can use the existing IC manufacturing equipment to make suspending microstructures with high aspect ratios.

### BACKGROUND OF THE INVENTION

1. Field of Invention

The invention relates to a fabrication method for microstructures and, in particular, to a fabrication method for making microstructures with high aspect ratios using IC manufacturing technologies.

2. Related Art

Currently, there are many techniques that integrate microelectromechanical elements and integrated circuits (ICs) on a single chip. One of them is the suspending microelectromechanical element. Such a structure is formed by etching to remove the silicon substrate under the microelectromechanical elements once the IC layout is completed.

The comb actuator, as a suspending microstructure, uses electrostatic forces to displace the suspending structure, producing the power for other micromechanical structures. Another example is the accelerometer. The external force makes the suspending mass block displace and changes the charges on the electrodes, thereby measuring the acceleration of the object. One feature of these devices is that they are microelectromechanical devices with high aspect ratios.

The microstructure with a high aspect ratio is usually used in mechanical devices with a large spring constant K. This is because the mechanical devices with a large spring constant require a shorter response time. This can be achieved only using microstructures with high aspect ratios.

There have been many methods proposed to make microstructures with high aspect ratios. An example is “Microstructures And Single Mask, Single-crystal Process For Fabrication Thereof” proposed by Kevin A. Shaw, Z. Lisa Zhang, and Noel C. MacDonald (in the U.S. Pat. Nos. 5,719,073, 5,846,849, and 6,051,866). The main technical character of their technique is to use photolithography processes, thin-film deposition processes, and dry etching processes to define the microstructures. The main steps are as follows. First, an oxide thin film is deposited as a mask layer. The photolithography process is then used to define the mask shape. Afterwards, the anisotropic etching is employed to define a high aspect ratio structure. Another oxide thin film is then deposited thereon. The thin film at the bottom of grooves is removed by etching. The silicon substrate is etched in the anisotropic way. Isotropic etching is then used to remove the bottom of the structure so that the structure is suspended. Finally, a metal layer is deposited as an electrode.

There are still improvements to be made in the above-disclosed technology. For example, many photolithography and thin-film deposition processes are required when making the high aspect ratio structures in order to define a microstructure. Anisotropic etching is used to define the microstructure with a high aspect ratio. Finally, the microstructure suspension process is performed in an etching channel.

On the other hand, one has to etch both the polysilicon layer and the silicon dioxide dielectric layer between the polysilicon layer and the silicon substrate before performing isotropic etching on the silicon substrate. In the suspension process, it takes a longer time to use dry etching. Wet etching, however, is likely to damage the metal electrode. In general, the number of photolithography processes is the main factor that determines the difficulty of the manufacturing process. In other words, the above-mentioned method is rather complicated.

### SUMMARY OF THE INVENTION

In view of the foregoing, an objective of the invention is to provide a fabrication method for microstructures with high aspect ratios. A suspending microstructure with a high aspect ratio can be formed using IC layout technique and subsequent etching procedures.

The disclosed technology uses via plugs connecting metal layers and contact plugs connecting the first metal layer and the silicon substrate to define the etching channel on the silicon substrate. At the same time the microstructure is completed, an etching channel is simultaneously formed using the above method. In other words, the etching channel is formed with the microstructure. Finally, isotropic etching is employed to etch the silicon substrate until the microstructure suspends.

In order to achieve the above objective, the disclosed fabrication method includes the following steps. First, a substrate is provided. The silicon substrate surface is deposited in order various thin films to form a microstructure and an etching channel. The etching channel is formed by using via plugs and contact plugs to penetrate through the dielectric layers. Finally, a dry etching gas is supplied via the etching channel to etch the substrate under the microstructure, making a suspension microstructure.

### BRIEF DESCRIPTION OF THE DRAWINGS

The invention will become more fully understood from the detailed description given hereinbelow illustration only, and thus are not limitative of the present invention, and wherein:

FIG. 1 is a schematic view of a conventional 1P3M CMOS stacked structure;

FIG. 2 is a schematic view of the disclosed microstructure;

FIG. 3 is a schematic view of the disclosed suspending microstructure with a high aspect ratio; and

FIGS. 4A through 4G are schematic view of steps in the fabrication process of making the disclosed suspending microstructure with a high aspect ratio.

### DETAILED DESCRIPTION OF THE INVENTION

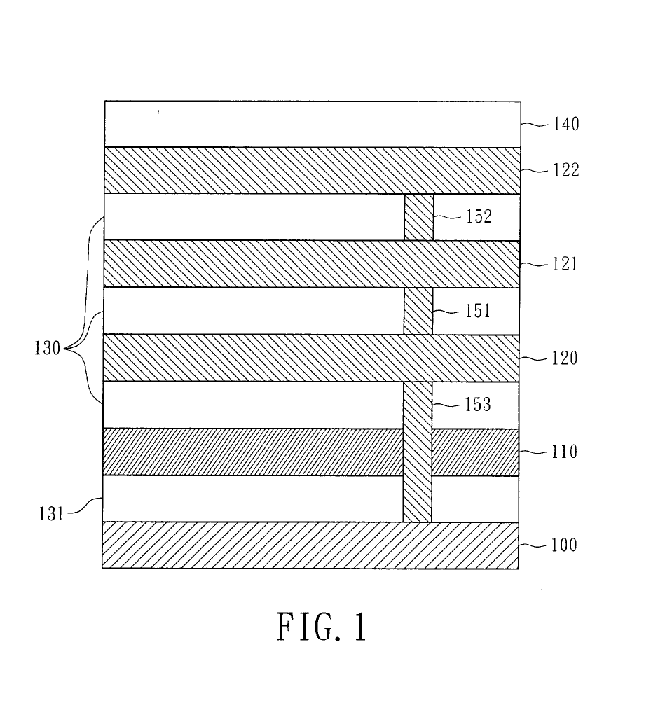

Please refer to FIG. 1, which shows the stacked structure of a single ploy three metal (1P3M) complementary metal-oxide semiconductor (CMOS). The stacked structure is formed by forming on the surface of the silicon substrate 100 a desired multi-layer circuit structure, including a polysilicon layer 110, a first metal layer 120, a second metal layer 121, a third metal layer 122, and a dielectric layer 130 in between. A first via plug 151 is formed between the first metal layer 120 and the second metal layer 121. A second via plug 152 is formed between the second metal layer 121 and the third metal layer 122. A contact plug 153 is formed between the first metal layer 120 and the silicon substrate 100. The third metal layer 122 is covered with a passivation to prevent the IC from external impurities and mechanical damages. Moreover, a field oxide layer 131 is formed between the polysilicon layer 110 and the silicon substrate 100.

The contact plugs and the via plugs are techniques used in multiple metalization processes. The contact plug refers to the embedding connecting various electrodes of an MOS transistor to the metal layer. The via plug is used to communicate different upper and lower metal layers. To avoid short circuits, a dielectric layer is inserted between two metal layers.

From FIG. 1 one sees that if the first via plug 151, the second via plug 152 and the contact plug 153 are designed at the same position, an etching channel can be readily formed at the same time layers of microstructure are deposited. After the microstructure process is done, one can use the etching channel to etch the silicon substrate 100 in order to make a suspending microstructure. In the prior art, the contact is not directly formed to reach the silicon substrate; it only reaches the polysilicon layer. Therefore, additional photolithography and etching are required once the previous etching reaches the silicon substrate.

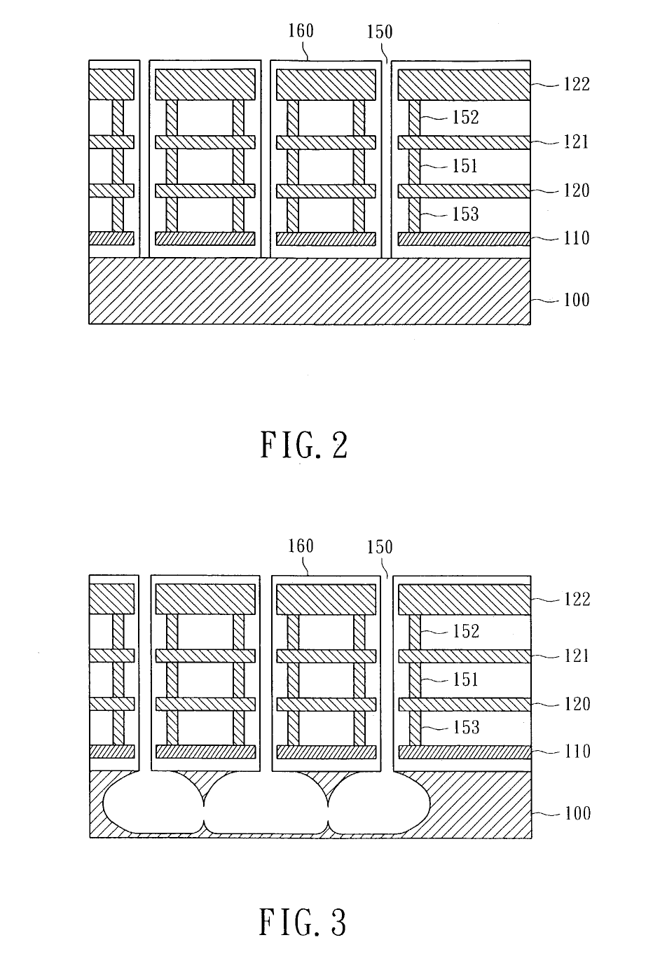

In other words, the stacked structure of the dielectric layers and metal layers is viewed as a microstructure. Via plugs and contact plugs are formed to penetrate through various thin films to define the shape of the microstructure. After breaking the dielectric thin films, the via plugs and the contact plug form an etching channel. The third metal layer and the passivation layer are masks of the silicon substrate. Anisotropic etching is performed to etch down to the silicon substrate. This completes the process of making a microstructure and an etching channel (see FIG. 2).

Afterwards, dry etching is performed. A dry etching gas such as SF₆ or XeF₂ goes through the etching channel 150 to etch the silicon substrate until the microstructure suspends (FIG. 3). This forms a microstructure with a high aspect ratio.

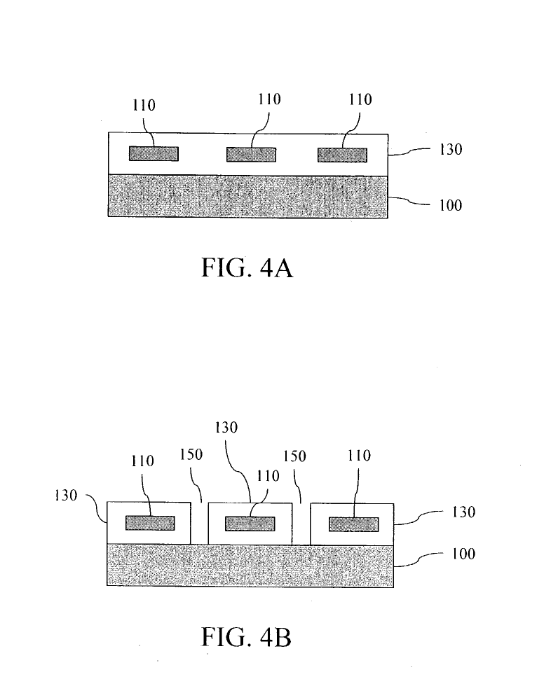

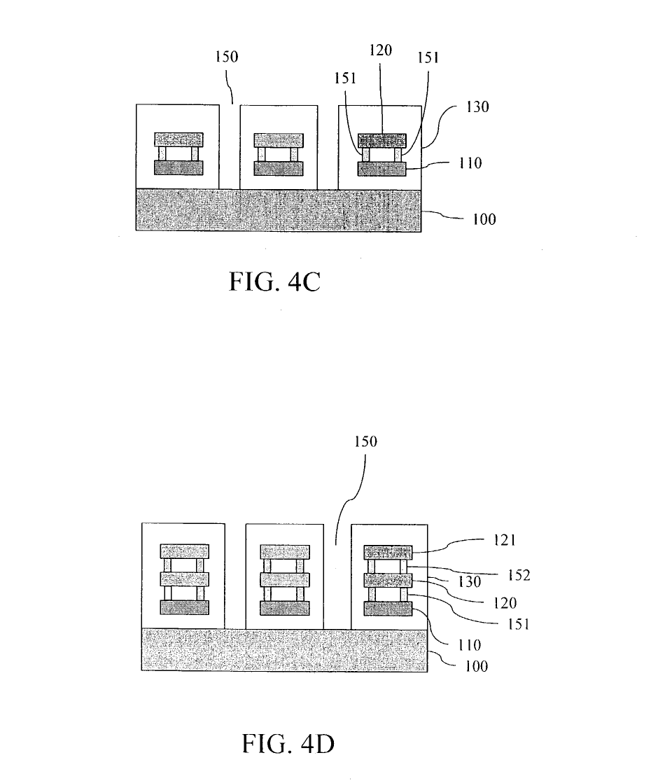

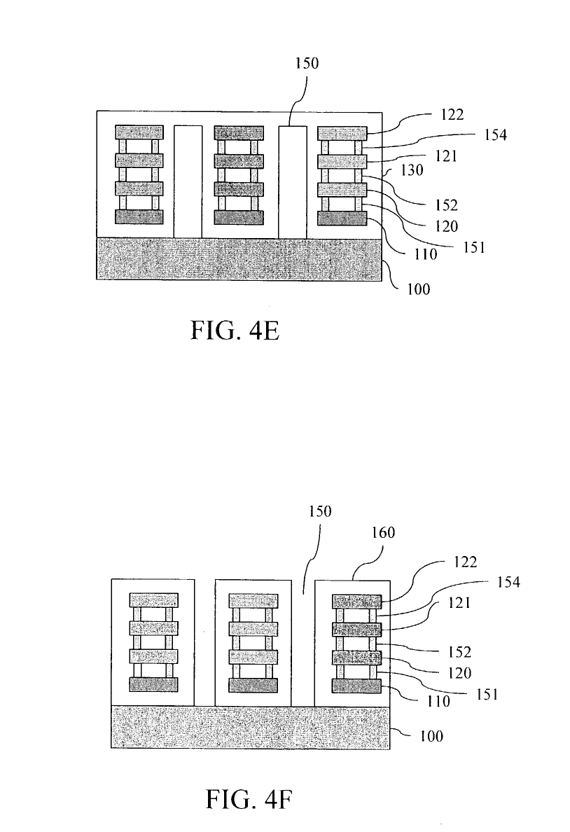

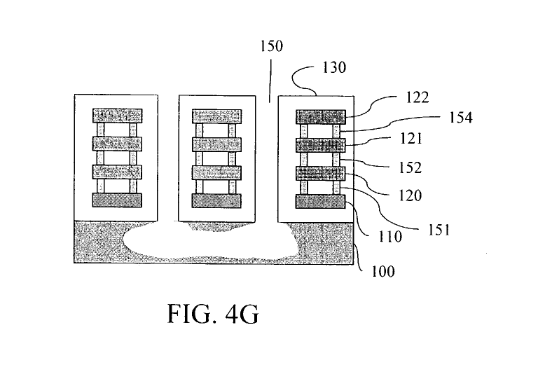

We use a 1P3M structure as an embodiment to explain the above concept. Please refer to FIGS. 4A through 4G. First, a silicon substrate 100 is formed with a polysilicon layer 110 and a dielectric layer 130 using photolithography, deposition, and etching processes (FIG. 4A). The dielectric layer 130 is formed with a contact plug to form an etching channel 150 (FIG. 4B). The process of forming the etching channel 150 includes the step of transferring the pattern at the contact plug position to the photoresist above the dielectric layer using the photolithography process. Afterwards, dry etching is employed to remove the dielectric layer no protected by the photoresist through anisotropic etching. The pillar hollow left in the dielectric layer after etching is the position to insert a plug. However, the invention does not insert a plug, but leaves it as the etching channel for etching the silicon substrate.

Moreover, the first via plug 151 and the first metal layer 120 are completed. The same process is used to form the etching channel 150 (FIG. 4C). The second via plug 152 and the second metal layer 121, the third via plug 154 and the third metal layer 122 are formed (shown in FIGS. 4D and 4E, respectively). Finally, a passivation layer is deposited to complete the microstructure 160.

Once the above procedure is completed, the passivation layer is etched (FIG. 4F) to form a complete etching channel 150. From the drawing, we observe that the metal on the sidewall structure is covered by a dielectric layer 130. Therefore, no metal contact occurs among the structures to have a short circuit.

Finally, the suspension process is performed for the microstructure 160. Isotropic dry etching reaction gas (such as SF₆ and XeF₂) is applied to etch the silicon substrate until it suspends (FIG. 4G).

The invention is able to remove the silicon substrate at the bottom of a device to make the structure suspend by utilizing the IC layout techniques and a single etching process. Therefore, it has the following advantages:

1. No additional photolithography process is required to complete the microstructure. Only a single dry etching process is needed.

2. Isotropic etching is employed to make the structure suspend.

3. Dielectric layers are used to protect the IC and the microelectromechanical devices to avoid damages caused by etching.

4. The passivation layer and metal layers are used as masks of the silicon substrate to increase the silicon etching ratio.

5. The metal on the sidewall structure is covered by a dielectric layer. Thus, no short circuit will occur because of metal contacts.

Certain variations would be apparent to those skilled in the art, which variations are considered within the spirit and scope of the claimed invention.

What is claimed is:

1. A fabrication method for making a microstructure with a high aspect ratio, the method comprising the steps of:
providing a substrate;
depositing in order a plurality of dielectric layers, a plurality of metal layers, and a plurality of polysilicon layers to form a microstructure and a contact plug;
wherein the plurality of metals are connected using a plurality of via plugs and the via plugs are not inserted with metal, forming an etching channel; and
etching through the etching channel the substrate under the microstructure so that the microstructure suspends and has a high aspect ratio.

2. The fabrication method of claim 1, wherein the substrate is a silicon substrate.

3. The fabrication method of claim 1, wherein the dielectric layers are silicon dioxide dielectric layers.

4. The fabrication method of claim 1, wherein the plurality of metal layers are formed from aluminum, copper and their alloys.

5. The fabrication method of claim 1, wherein the etching channel is completed using an anisotropic etching process.

6. The fabrication method of claim 1, wherein the step of etching through the etching channel the substrate under the microstructure employs an isotropic etching process.

7. The fabrication method of claim 1, wherein the step of etching through the etching channel the substrate under the microstructure employs one method selected from dry etching and wet etching.

8. The fabrication method of claim 7, wherein the etchant of the wet etching is a sulfuric acid etchant formed with an appropriate ratio.

9. The fabrication method of claim 7, wherein the etching gas in the dry etching is one selected from SF₆ and XeF₂.
